(19) United States
(12) Patent Application Publication
(10) Pub. No.: US 2020/0381286 A1
(43) Pub. Date: Dec. 3, 2020

(54) CARRIER HEAD MEMBRANE WITH A BEAD

(71) Applicant: Applied Materials, Inc., Santa Clara, CA (US)

(72) Inventors: Young J. Paik, Campbell, CA (US); Melvin Barrentine, Austin, TX (US); Abhijit Y. Desai, Fremont, CA (US); Hai Nguyen, Austin, TX (US); Ashish Bhatnagar, Fremont, CA (US); Rajkumar Alagarsamy, Sunnyvale, CA (US)

(21) Appl. No.: 16/986,192

(22) Filed: Aug. 5, 2020

Related U.S. Application Data
(62) Division of application No. 15/592,038, filed on May 10, 2017.
Application No. 15/592,038 is a continuation of application No. 12/409,371, filed on Mar. 23, 2009, now abandoned.
(60) Provisional application No. 61/039,246, filed on Mar. 25, 2008.
(60) Provisional application No. 61/039,249, filed on Mar. 25, 2008.

(51) Int. Cl. H01L 21/683; B24B 37/30

(52) U.S. Cl. CPC H01L 21/6838; B24B 37/30; H01L 21/30625; Y10T 428/24355; Y10T 428/24612

(57) ABSTRACT

A method and apparatus for planarizing a substrate are provided. A substrate carrier head with an improved cover for holding the substrate securely is provided. The cover may have a bead that is larger than the recess into which it fits, such that the compression forms a conformal seal inside the recess. The bead may also be left uncoated to enhance adhesion of the bead to the surface of the groove. The surface of the cover may be roughened to reduce adhesion of the substrate to the cover without using a non-stick coating.

### CROSS-REFERENCE TO RELATED APPLICATIONS

This application is a divisional of U.S. patent application Ser. No. 15/592,038, filed May 10, 2017, which is a continuation of U.S. patent application Ser. No. 12/409,371, filed Mar. 23, 2009, which claims priority to U.S. Provisional Application Ser. No. 61/039,249, filed on Mar. 25, 2008 and claims priority to U.S. Provisional Application Ser. No. 61/039,246, filed on Mar. 25, 2008, the disclosures of which are incorporated by reference.

### TECHNICAL FIELD

This disclosure relates generally to apparatuses and methods for semiconductor manufacturing. Specifically, embodiments relate to apparatuses for planarizing semiconductor substrates and methods of forming the apparatuses.

### BACKGROUND

In the semiconductor manufacturing industry, planarization is a process of removing material from a substrate, smoothing a surface of the substrate, and exposing layers beneath the surface of the substrate. Substrates typically undergo planarization after one or more deposition processes builds layers of material on the substrate. In one such process, openings are formed in a field region of the substrate and filled with metal by a plating process such as electroplating. The metal fills the openings to create features, such as wires or contacts, in the surface. Although it is desired that the openings be filled with metal only to the level of the surrounding substrate, deposition occurs on the field region as well as the openings. This extra unwanted deposition must be removed, and planarization is the method of choice for removing the excess metal.

Chemical Mechanical Planarization (CMP) is one of the more common types of planarization processes. A substrate is held firmly in place and scrubbed with an abrasive pad or web. The substrate may be rotated against a web as the web is translated linearly beneath the substrate, or the substrate may be rotated against a pad while the pad is also rotated in the same or opposite direction, translated linearly, translated in a circular motion, or any combination of these. An abrasive composition is frequently added to the scrubbing pad to accelerate material removal. The composition typically contains abrasive materials to scour the substrate, and chemicals to dissolve material from the substrate surface. In the case of Electro-Chemical Mechanical Planarization, a voltage is also applied to the substrate to accelerate removal of material by electrochemical means.

The forces applied to the substrate surface during such processes can be considerable. The scrubbing process typically generates shear forces of up to 100 pounds per square inch (psi) at the surface of the substrate, while vertical movement of the substrate into and out of processing position can result in axial forces of up to 10 psi. These forces require that the substrate be firmly held in place before, during, and after processing to ensure uniform results and to guard against substrate breakage.

In most embodiments, the substrate is held in place by a carrier head, such as the example shown in the schematic cross-sectional diagram of FIG. 1. Carrier head 100 features a substrate engagement portion 102. The substrate engagement portion 102 is fitted with a membrane or diaphragm 104. The membrane 104 contacts the substrate being held by the carrier head 100. The carrier head 100 also generally features one or more passages 106. The passages 106 allow gas to be pumped into or out of the carrier head 100 to control the shape of the membrane 104. In operation, the carrier head 100 will contact a substrate by pressing the membrane 104 against the substrate. Gas will be pumped out of the carrier head 100 through passage 106, creating a vacuum behind the membrane 104. The membrane 104 becomes concave, creating a vacuum between the membrane 104 and the substrate. The difference in pressure between the substrate surface facing the carrier head 100 and the surface facing away from the carrier head 100 forces the substrate against the carrier head, creating a “vacuum chuck.” The carrier head 100 thus holds the substrate firmly during processing. To release the substrate after processing, gas is pumped into the carrier head 100 through the passage 106. This relieves the vacuum, returning the membrane 104 to its planar position, releasing the vacuum chuck.

Generally, the membrane 104 is attached to the carrier head 100 by virtue of a bead 108 at the edge of the membrane 104 that engages a groove 110 in the carrier head 100, as illustrated in FIG. 1A. The bead 108 is a shaped edge feature that is sized to fit within groove 110. In some cases, the elasticity of the membrane holds the bead 108 in the groove 110, and keeps the membrane 104 attached to the carrier head 100. The force of the contact between the substrate and the membrane 104 creates a frictional force that resists lateral motion of the substrate during processing. The vacuum chuck also holds the substrate against the carrier head for lifting above the processing surface.

Unfortunately, membranes commonly used in today's carrier heads have significant leakage rates. Membrane leakage impairs maintenance of vacuum behind the membrane, allowing the substrate to decouple from the carrier head during processing. In general, the vacuum chuck should be forceful enough to withstand the shear forces that develop during planarization. If the vacuum force is too low, the shear force overcomes the frictional force and the substrate detaches from the carrier head. This often results in damage to the substrate, rendering it unusable. Substrates that decouple from processing equipment frequently damage other substrates on the production line. It is often necessary to shut down production lines to remove damaged substrates.

Substrates also stick to the membrane. After processing, portions of a substrate that were forcefully urged against the membrane surface adhere to the membrane, making it difficult to remove the substrate from the apparatus. Even when pressure is applied to one or more of the chambers to de-chuck the substrate, the substrate may adhere to the membrane and resist de-chucking. Substrates that adhere to a carrier head longer than desired may also be damaged.

Thus, there is a continuing need for a carrier head capable of holding a substrate firmly during planarization and releasing it reliably after processing.

### SUMMARY

Embodiments generally provide a carrier head and cover for manipulating substrates in a planarizing apparatus.

In one aspect, a cover for a substrate carrier head is provided, comprising a surface for engaging the substrate, and a bead at the edge of the surface for engaging a receiving structure on the carrier head, wherein the width of the bead is larger than the width of the receiving structure. The carrier head has an upper portion and a lower portion, with the receiving structure formed therein. The lower portion is mated to the upper portion in a way that allows the lower portion to move with respect to the upper portion. A seal is formed between the membrane and the carrier head by forming a bead on an edge portion of the membrane, the bead having a thickness greater than the width of the receiving structure, inserting the bead into the receiving structure, and compressing the bead to conform to the receiving structure.

In another aspect, a membrane for a substrate carrier head is provided, comprising a mounting surface for engaging the substrate, a peripheral portion extending from the mounting surface, a bead extending from the peripheral portion, and a non-stick coating covering a portion of the membrane to form a coated portion and an uncoated portion, wherein the uncoated portion includes the bead. The carrier head comprises a base, to which the membrane is coupled, and the uncoated bead adheres to the base, enhancing the seal formed thereby. The non-stick coating is applied to portions of the membrane by applying a mask over parts of the membrane that are to remain uncoated, applying the non-stick coating, and removing the mask.

In another aspect, a membrane for a substrate carrier head includes a surface for engaging the substrate and a bead at the edge of the surface for engaging a receiving structure in the carrier head. The surface has an Ra roughness at least about 10 micro-inches.

Implementations may include or more of the following features. The receiving structure may be a groove. The surface may have an Ra roughness at least about 15 micro-inches. The surface may adhere to a substrate with a sticking force less than about 0.02 lbs, e.g., less than about 0.01 lbs. The receiving structure may be formed in a base portion of the carrier head, and the base portion may be moveably coupled to a housing portion of the carrier head. The surface may adhere to a substrate with a sticking force less than the weight of the substrate.

In another aspect, a membrane for a substrate carrier head includes a mounting surface for engaging the substrate, a peripheral portion extending from the mounting surface, a bead extending from the peripheral portion, and a non-stick coating covering a portion of the membrane to form a coated portion and an uncoated portion. The uncoated portion includes the bead.

Implementations may include or more of the following features. The uncoated portion may include the peripheral portion. A leak rate of the membrane may be less than about 0.2 psi/min. A surface of the bead may adheres to metal with a sticking tension of at least 6.0 Pa. The bead may be adapted to engage with a receiving structure formed in a base portion of the carrier head, and the base portion may be moveably coupled to a housing portion of the carrier head.

In another aspect, a method of manipulating a substrate in a planarizing apparatus includes providing a carrier head having a membrane, engaging the substrate by pressing the surface of the membrane against the substrate and reducing the pressure behind the membrane to form a vacuum chuck, and disengaging the substrate by releasing the vacuum chuck. The membrane has a surface having Ra roughness at least about 0.10 micro-inches.

Implementations may include or more of the following features. The weight of the substrate may exceed the sticking force between the substrate and the surface of the membrane. Disengaging the substrate may further include allowing the substrate to separate from the surface of the membrane by its own weight. The substrate may adhere to the surface of the membrane with a sticking force less than about 0.01 lbs. Providing the membrane may include providing a curable liquid to a mold having an internal surface designed to impart surface roughness to at least a portion of the membrane, setting the liquid to form the membrane, and removing the membrane from the mold. Providing the membrane may include providing a curable liquid to a mold, setting the liquid to form the membrane, removing the membrane from the mold, and applying mechanical force to roughen a surface of the membrane.

In another aspect, a method of forming a membrane for a planarizing apparatus includes forming a flexible article with a flat central portion, a contoured peripheral portion, and a bead around the edge, applying a mask to a portion of the flexible article, coating the article with a non-stick coating, and removing the mask.

Implementations may include or more of the following features. The flexible article may be formed from a material selected from the group comprising silicone rubber, butyl rubber, natural rubber, EPDM rubber, polyimide, and thermoplastic elastomer. Masking a portion of the flexible article may include fitting a flexible covering over a portion of the article. The masked portion of the article may include the bead. The non-stick coating may be a polymer coating, e.g., a parylene coating. Forming the flexible article may include providing a curable liquid to a mold, heating the liquid to cure, and removing the flexible article from the mold.

In another aspect, a membrane for a substrate carrier head includes a surface for engaging the substrate, and a bead at the edge of the surface for engaging a receiving structure on the carrier head. The width of the bead is larger than the width of the receiving structure.

Implementations may include or more of the following features. The receiving structure may be a groove. The width of the bead may be at least about 10% larger than the width of the receiving structure. The thickness of the membrane may be less than the width of the receiving structure. The bead may have a circular cross-sectional shape. The bead may undergo a compression ratio of at least about 10%, e.g., between about 12% and about 20%, when engaged with the receiving structure. Compression of the bead may result in a conformal seal inside the receiving structure. The surface may have an Ra roughness of at least about 10 micro-inches. A portion of the membrane may be coated with a non-stick coating to form a coated region and an uncoated region, and the uncoated region includes at least the bead. A surface of the bead may adhere to metal with a sticking tension of at least 6.0 Pa.

In another aspect, a carrier head for manipulating a substrate in a chemical mechanical polishing apparatus includes a housing, a base coupled to the housing, and a cover coupled to the base. The cover comprises a bead that engages a receiving structure on the base, and an uncompressed thickness of the bead is larger than the width of the receiving structure.

Implementations may include or more of the following features. The receiving structure may be a groove. The bead may undergo a compression ratio of at least about 10%, e.g., between about 12% and about 20%, when engaged with the receiving structure. The cover may have a leakage rate less than about 0.2 psi/min. The surface of the bead may conform to the surface of the groove to form a seal. The cover may further include a surface for engaging a substrate, and the surface may have an Ra roughness of at least about 10 micro-inches. A portion of the cover may be coated with a non-stick coating to form a coated region and an uncoated region, and the uncoated region may include at least the bead. A surface of the bead may adhere to metal with a sticking tension of at least 6.0 Pa.

In another aspect, a method of forming a seal between a substrate carrier head and a membrane includes providing a groove in a portion of the substrate carrier head, forming a bead around the edge of the membrane having thickness greater than the width of the groove, inserting the bead into the groove, and compressing the bead inside the groove such that the surface of the bead comforms to the surface of the groove to form a seal.

Implementations may include or more of the following features. The thickness of the bead may be at least about 10% greater than the width of the groove. Compressing the bead inside the groove may deform the bead to a compression ratio at least about 10%, e.g., between about 12% and 20%. Compressing the bead inside the groove may result in void space less than about 1% in the groove.

In another aspect, a membrane for a substrate carrier head is provided, comprising a surface for engaging the substrate, and a bead at the edge of the surface for engaging a receiving structure in the base, wherein the surface has an Ra roughness at least about 10 micro-inches. A bead on the membrane mates with a groove on the carrier head

### BRIEF DESCRIPTION OF THE DRAWINGS

So that the manner in which the above recited features can be understood in detail, a more particular description, briefly summarized above, may be had by reference to embodiments, some of which are illustrated in the appended drawings. It is to be noted, however, that the appended drawings illustrate only typical embodiments and are therefore not to be considered limiting of the scope of the claims, for other equally effective embodiments may be possible.

FIG. 1 is a cross-sectional schematic view of an exemplary prior art carrier head apparatus.

FIG. 1A is a detail view of the apparatus of FIG. 1.

FIG. 2 is a schematic cross-sectional view of an exemplary carrier head apparatus according to one embodiment.

FIGS. 2A and 2B are detail views of the apparatus of FIG. 2.

FIGS. 3A and 3B are a schematic cross-sectional view of two carrier head membranes according to embodiments.

FIG. 4A is a perspective view of an apparatus according to one embodiment.

FIG. 4B is a side view of a mask apparatus according to an embodiment.

FIG. 5 is a schematic cross-sectional view of a carrier head apparatus according to one embodiment.

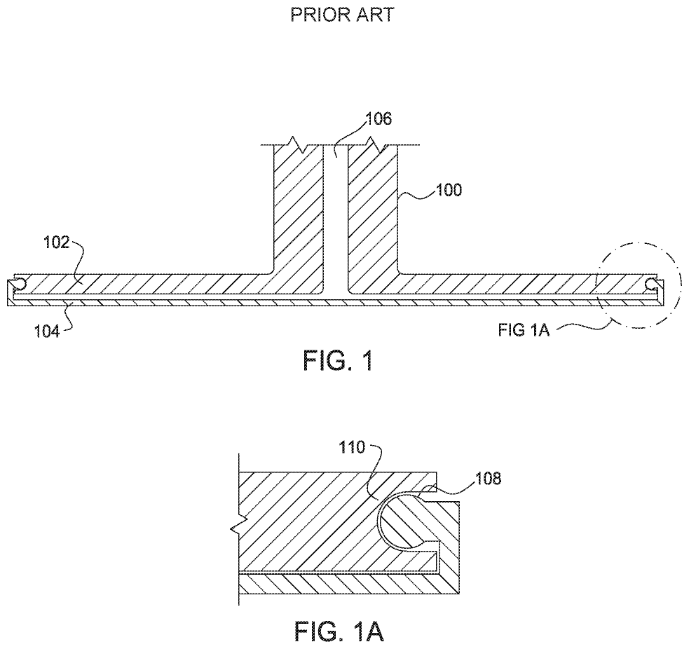

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

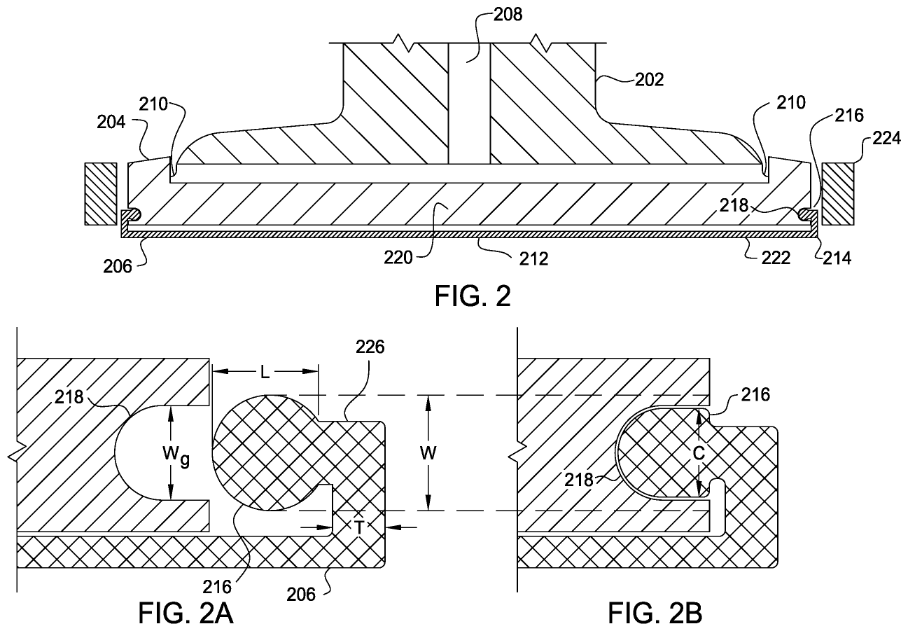

Embodiments generally provide a substrate carrier head for manipulating a substrate in a planarizing process. FIG. 2 depicts an exemplary carrier head 200 according to an embodiment. The carrier head 200 depicted in FIG. 2 has a housing 202, a base 204, and a membrane 206. The housing 202 generally provides structural support to the carrier head 200, attaches it to the rest of the apparatus (not shown), and provides a conduit 208 for passing process gases into and out of the carrier head 200. In some embodiments, base 204 is coupled to housing 202 by a flexible diaphragm 210 to allow a certain degree of independent movement between housing 202 and base 204. This allows adjustment of the substrate position relative to the work surface when a substrate is mounted on the carrier head 200 while maintaining a seal on the carrier head 200. Movement of the base 204 may be controlled by a mechanism (not shown), well-known in the art and exemplified by commonly-assigned U.S. Pat. No. 6,183,354, located within the base 204 and adapted to constrain movement of the base 204 relative to the housing 202. The diaphragm 210 may be made of any flexible material likely to withstand mechanical and chemical demands of the CMP process. Such materials may include elastomeric materials such as butyl rubber, EPDM rubber, natural rubber, or silicone rubber.

The base 204 is covered by the membrane 206 at a lower surface of the base 204. The membrane 206 generally comprises a surface 212, which engages a substrate, a peripheral portion 214, and a bead 216 at the edge of the membrane 206. The bead 216 is generally a shaped feature at the edge of the membrane, and in some embodiments may have a thickness that is greater than the thickness of the membrane surface 212. The bead 216 engages the base 204 by use of a groove 218 formed in the base 204. In some embodiments, the bead 216 is inserted into the groove 218 to install the membrane 206 on the base 204. The flexible membrane 206 stretches across the base 204, and together they cooperatively define a space 220 above the membrane. The pressure in the space 220 may be manipulated to create a vacuum behind the membrane 206. When the membrane surface 212 is in contact with a substrate, this vacuum deforms the membrane surface 212, pulling it away from the surface of the substrate. The edge portion 222 of the membrane surface 212 remains in contact with the substrate surface as the membrane surface 212 recedes, and a vacuum forms between the membrane surface 212 and the substrate surface. The pressure differential between the substrate surface facing the membrane and that facing away from the membrane produces a force that urges the substrate onto the carrier head, resulting in a “vacuum chuck.”

Embodiments provide methods and apparatuses for maintaining the vacuum chuck by preventing leakage through and around the membrane 206. FIG. 2A is a close-up view of the bead 216 and groove 218 assembly associated with membrane 206 of carrier head 200 shown in FIG. 2. The bead 216 has a width W that may be greater than the thickness T of the membrane 206. The bead may be generally circular in shape, having a cross-section that describes an arc of a circle, or it may be ovoid, oblong, or elliptical in shape, having a cross-section that describes an arc of a convex curve, such as an ellipse. A bead shaped in an ovoid, oblong, or generally non-circular fashion may have a first dimension L substantially parallel or coplanar with a bead attachment region 226 of the membrane 206, and a second dimension W substantially perpendicular to the attachment region 226 of the membrane 206. In some embodiments, W may be greater than L. In others, L may be greater than W.

The bead 216 is generally inserted into the groove 218 on the base 204. In carrier heads commonly used today, the groove 218 has a width W_{g} that is equal to or greater than the width W of the bead 216. In such “exact fit” assemblies, the bead 216 may be held inside the groove 218 by a retaining ring 224 that prevents the bead 216 from coming out of the groove 218. If the groove 218 is sized to fit exactly, or to be larger than the bead, significant void space may be left around the bead 216 to allow gases to pass around the bead 216 and through the groove 218. The inventors have discovered that using a bead 216 that is larger than the groove width W_{g} results in a compression seal that virtually eliminates gas leakage through the membrane 206. As shown in FIG. 2B, the bead 216 of width W may be compressed to a compression width C when inserted into the groove 218. The compression ratio may be defined as R=(W−C)/W, and may be expressed as a percent by multiplying the resulting fraction by 100. The compression ratio thus represents the degree to which the width of the bead 216 is reduced when inserted into the groove 218. Compression of the bead 216 inside the groove 218 creates a seal as the surface of the bead 216 conforms closely to the surface of the groove 218 under pressure, preventing passage of pressurized gases through the groove around the bead 216. Void space in the groove around the bead is reduced to less than 1%. A compression ratio of about 10% to about 25% may be used in most embodiments. A compression ratio of about 12% to about 20% is preferred, however. Using a bead larger than the receiving structure on the carrier head may reduce leakage rate of the membrane to 0.2 psi/min or less.

A membrane such as that described above and depicted in FIGS. 2A and 2B will generally be made of a flexible material that can withstand processing conditions such as high shear forces and acidic compositions. Durable polymeric materials such as silicone rubber, butyl rubber, natural rubber, EPDM rubber, polyimide, and thermoplastic elastomer may generally be useful for forming a carrier head membrane.

Substrates stick to membranes covering carrier heads in CMP apparatuses. The sticking can sometimes result in damage to substrates and production shutdowns. A substrate that sticks to the carrier head membrane may not disengage at the proper time and may be damaged by substrate handling machinery. Such damaged substrates may leave shards or particles behind that damage subsequent substrates, resulting in a series of lost substrates. Moreover, it may be necessary to shut down the production line to remove the pieces.

To combat substrates sticking to carrier head membranes, manufacturers have commonly coated the membranes with a non-stick coating, such as parylene. The parylene coating process is a low-pressure vapor phase deposition process. Parylene dimer, also known as diparaxylylene, is vaporized and pyrolyzed to yield the paraxylylene diradical, which deposits and polymerizes into polyparaxylylene on the membrane. The coating covers the membrane conformally, and eliminates the tendency for a substrate to stick to the membrane. However, it also reduces the ability of the membrane bead to conform to its groove, resulting in high rates of gas leakage.

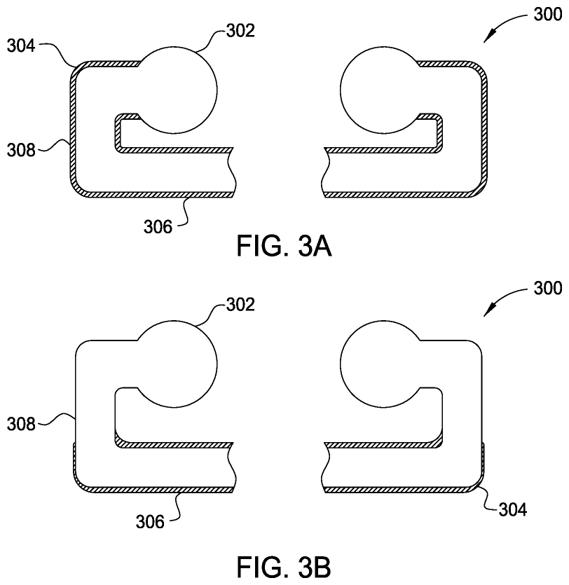

Embodiments provide methods and apparatuses for a carrier head featuring a membrane with reduced tendency to stick to substrates and with a bead that conforms to a receiving structure on the carrier head. FIG. 3A is a cross-sectional view of a carrier head membrane 300 according to one embodiment. The carrier head membrane of FIG. 3A has a bead 302, and is coated with a non-stick coating 304 that extends up to the bead 302 but does not cover the bead. The non-stick coating 304 thus covers only the mounting surface 306 and the peripheral portion 308 of the membrane 300. Leaving the bead 302 uncoated utilizes the natural tendency of the uncoated portion of the membrane 300 to stick to other surfaces to enhance sealing. In many embodiments, to install the membrane 300 on a carrier head, the bead 302 is inserted into a recessed portion, such as a groove, formed on the base of the carrier head (not shown). The uncoated bead of FIG. 3A conforms to the recessed portion more easily because the uncoated surface of the membrane 300 is more resilient than the coated surface. Additionally, the surface of the bead 302 adheres to the internal surface of the recessed portion, enhancing the seal formed thereby. In some embodiments, the material of the membrane, such as the surface of the bead, generally adheres to metal with a sticking force at least about 6.0 Pascals (Pa). In other embodiments, the force required to separate the bead from the base is at least about 0.5 milliNewtons (mN).

FIG. 3B is a cross-sectional view of a carrier head membrane according to another embodiment. In the embodiment of FIG. 3B, the non-stick coating 304 extends up to a peripheral portion 308 of the membrane. The non-stick coating thus covers only the mounting surface 306, and the peripheral portion 308 and the bead 304 comprise an uncoated surface. In alternate embodiments, a non-stick coating may be applied to the bead 302 that is thinner than that applied to the mounting surface 306. For example, in some embodiments, a non-stick coating comprising parylene or polyparaxylylene may be applied to a thickness of 50 microns (μm) on the mounting surface 306, but only 10 μm on the bead 302. The thinner non-stick layer on the bead 302 enhances the ability of the bead 302 to conform to the recessed portion of the base to form a seal, while reducing the detachment force required to remove the bead 302.

Other embodiments provide a carrier head membrane that does not require a non-stick coating such as that described above to release substrates reliably. A carrier head membrane may be formed with a surface for engaging the substrate that has low sticking force, such as less than 0.02 lbs., for example less than 0.01 lbs., without forming a non-stick coating on the surface. A carrier head membrane having a surface with Ra roughness at least about 10 micro-inches (pin), such as at least about 15 pin, will have sticking force that is less than the weight of a substrate, such that a substrate will not stick to the membrane surface as the carrier head is disengaged from the substrate. Such a carrier head membrane may be formed in a molding process, such as compression or injection molding, using a mold designed to impart the desired surface roughness. Alternately, the surface roughness may be imparted after the membrane is formed by applying a surface roughening article to the desired surface. Such an article may abrade the surface to roughen it, or it may be a laminate with a rough surface that adheres to the smooth molded surface of the membrane to impart a rough surface. If desired, the non-stick quality of the rough surface may be enhanced by application of a non-stick coating, such as that described above, to a portion of the rough surface of the membrane, or to the entire membrane having the rough surface.

A carrier head may be provided having any or all of the characteristics described above. In one example, a carrier head may have an upper portion and a lower portion mated therewith, such that the lower portion can move with respect to the upper portion, as described above in connection with FIG. 2. A recess, formed to be a receiving location for a cover, such as a groove, may be formed in the lower portion. The recess may have a rounded profile or an angled profile, such as a square or rectangular profile, and may have width that is greater than, equal to, or less than its depth, depending on the embodiment.

A cover may be provided for the carrier head to facilitate handling of substrates. The cover may be a membrane formed from a pliable material, such as a flexible polymer. The cover may be coated with a non-stick coating over its entire surface or a portion thereof. The cover will generally have a central portion with a surface for engaging or mounting a substrate thereon, a peripheral portion that facilitates mating with the carrier head, and an edge portion that mates with the carrier head. The edge portion of the cover may be a bead, and may be generally round in shape, such as circular, ovoid, or oblong, or angular in shape. The edge portion will generally be formed to fit into the recessed portion of the carrier head. The size and shape of the edge portion may be configured to fit the size and shape of the recessed portion exactly, or is preferably configured to be wider than the recessed portion, such that compression is required to insert the edge portion into the recessed portion. A compression ratio, defined as the percent reduction in width upon compression, of about 10% to about 25%, such as about 12% to about 20%, may be useful in controlling leakage of gases around the cover to about 0.2 psi/min or less. An edge portion that is at least 10% larger in width than the recess into which it is to be inserted generally results in a workable seal. The cover may have thickness that is greater than the width of the edge portion or less than the width of the edge portion, depending on the embodiment. The cover will generally define one or more spaces or cavities within the carrier head for manipulating the pressure behind the cover. Manipulating the pressure behind the cover allows the shape of the cover to be changed to meet process objectives.

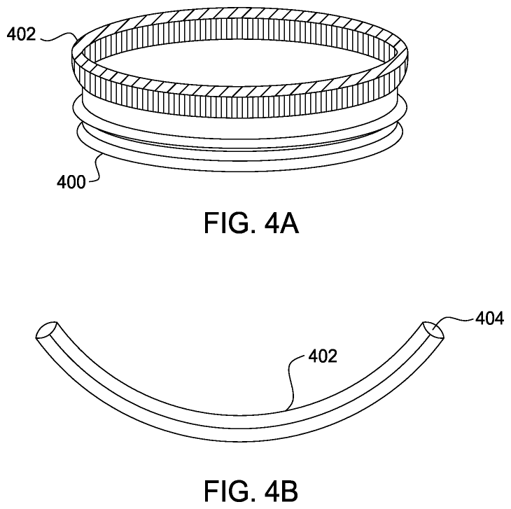

The cover may be coated with a non-stick coating. A non-stick coating deposited from a vapor, such as a parylene coating, or a coating applied as a liquid, may be used. The non-stick coating may be applied over the entire surface of the cover, or over only a portion of the surface. For example, a non-stick coating may be applied over all but the edge portion, or only on the substrate engaging surface. A mask may be used during the coating application process to protect portions of the cover that are not to be coated. The mask may be a fixture with a shape similar to that of the edge portion, with an opening that allows the mask to fit onto the cover. FIG. 4A is a perspective view of a cover 400 with a mask 402 installed. In one embodiment the mask 402 may be a flexible tubular fixture with a longitudinal opening 404 along its length, as shown in FIG. 4B. In another embodiment, the mask 402 may be a flexible, hollow, rectangular sleeve with a longitudinal opening. The opening 404 allows the edge portion of the cover to be inserted into the mask during application of the non-stick coating. When installed on the cover 400, the mask 402 may be torroidal in shape. The mask 402 may be removed after applying the non-stick coating to yield the cover 400 with the non-stick coating over a portion of its surface. It may be advantageous, in some embodiments, to mask the edge portion, or the edge and the peripheral portion, of the cover. A non-stick coating may reduce the ability of the edge portion to seal the recess by reducing the affinity of the cover material, such as silicone rubber, EPDM rubber, butyl rubber, natural rubber, or other elastomeric or thermoplastic material, for the carrier head material, such as metal. The reduced affinity leads to a reduced seal and an increased leak rate. Leaving the edge portion, or the edge and peripheral portions, uncoated preserves the ability of the edge portion to conform to the recess and form the required seal.

In some embodiments, the cover may be formed with a roughened substrate engaging surface, rather than a non-stick coating. A cover such as that described above is generally formed by a molding process in which a curable or settable material is disposed in a mold and allowed to form to the mold and set. A mold may be used that imparts a surface roughness to selected parts of the formed cover. Surface roughness, Ra, of at least 10 pin, such as about 15 pin or more, reduces the sticking force in many embodiments to less than about 0.02 lbs, so that the weight of a substrate exceeds the sticking force and the substrate disengages from the carrier head. Surface roughness may also be imparted to a cover by application of mechanical force to the selected surface of the cover. A roughening tool may be used to scuff or abrade the surface of the cover to impart roughness. Alternately, a laminate having a rough surface may be applied to the cover in some embodiments.

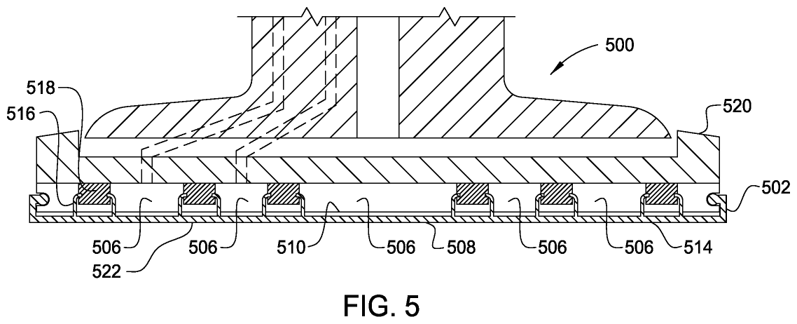

Some covers may be sectional in construction, having dividers extending from a surface of the cover and defining chambers. FIG. 5 is a schematic cross-sectional view of a carrier head 500 with a sectional cover 502. The dividers 516 may conform to attachment points 518 on the base 520 of the carrier head 500, and may seal the chambers 506 when mated to the attachment points 518. The carrier head 500 with sectional cover 502 will generally have passages 504 communicating between a gas source external to the carrier head (not shown) and the chambers 506 so that gas can be independently provided to the chambers 506 or evacuated from the chambers 506. In operation, the chambers 506 may be pressured to different degrees to shape the substrate engagement surface 522. It may be advantageous, in some embodiments, to apply a non-stick coating 508 to a portion of the substrate engaging surface 522 depending on how the chambers 506 are operated. For example, if concentric chambers are provided so that the center of the substrate engaging surface 522 may be pressured or evacuated to enhance handling of the substrate, it may be advantageous to apply a non-stick coating only to the central portion 510 of the substrate engaging surface corresponding to the most central chamber. If the periphery of the substrate sticks to the peripheral portion 514 of the substrate engaging surface 522, the chamber 506 closest to the center of the cover 502 may be pressured into a convex shape to disengage the substrate from the peripheral portion 514, and the non-stick character of the central portion 510 of the substrate engaging surface 522 will ensure the substrate disengages from the carrier head 500 reliably. Likewise, it may be advantageous in some embodiments to create surface roughness for a portion of the substrate engaging surface 522. In some embodiments, a single cover may have portions with non-stick coating and other portions with roughened surfaces.

In operation, a carrier head fitted with a cover as described above may be used to manipulate substrates reliably on a planarizing apparatus. Referring again to FIG. 5, the substrate engaging surface 522 of the cover 502 is moved into proximity with the substrate, the center of the surface 522 aligning with the center of the substrate for best results. The surface 522 is urged against the substrate, and the space inside the carrier head behind the cover is evacuated. In embodiments with sectional covers, one or more of the chambers may be evacuated. In embodiments with covers that are not sectional, substantially the entire space behind the cover is evacuated. The vacuum thus created behind the cover 502 distorts the substrate engaging surface 522 into a concave shape, creating a space between the substrate engaging surface 522 and the substrate that is sealed by contact between the peripheral portion 514 of the cover 502 and the periphery of the substrate. This vacuum holds the substrate tightly against the carrier head 500 during processing. A cover such as that described herein maintains the vacuum with a very low leak rate. The substrate is held securely by the carrier head throughout processing. To release the substrate, the vacuum behind the cover may be relieved with atmospheric pressure to disengage the substrate. If the substrate engaging surface 522 has a non-stick coating or a surface roughness as described above, the substrate will disengage spontaneously. If portions of the substrate engaging surface are coated or roughened, such as the central portion, and the substrate sticks, a positive pressure may be applied to deform the cover in a convex shape to disengage the periphery of the substrate, after which the center of the substrate will disengage spontaneously. This may be advantageous to prevent an unwanted detachment of the substrate from the carrier head at inconvenient times.

Embodiments provide a method of forming a seal between a substrate carrier head and a membrane. A carrier head is provided with a recessed portion, which may be a groove or other receiving structure. The recessed portion may have any convenient shape, but most common is a rounded or U-shape, or a rectangular shape. A membrane is provided for fitting to the carrier head, the membrane having a surface for engaging the substrate, a peripheral portion for facilitating a seal extending from the substrate engaging surface, and an edge portion for mating and sealing with the carrier head extending from the peripheral portion. A bead may be formed on the edge portion of the membrane with thickness greater than a thickness of the membrane. Alternately, portions of the membrane may have a thickness greater than the thickness of the bead. The bead may also have any convenient shape, but will commonly have a circular, oblong, or oval cross-sectional shape.

The thickness of the bead is larger than the width of the recessed portion to which it is to mate. A bead having a thickness at least about 10% greater than the width of the recessed portion is preferred. The bead is compressed when inserted into the recessed portion, such that the surface of the bead forms a conformal seal with the surface of the recessed portion. When inserted into the recessed portion, the bead will generally be deformed, resulting in a compression ratio, defined as the percent reduction in width or thickness, of between about 10% and about 25%, such as between about 12% and about 20%, and leaving residual void space of less than 1% inside the recessed portion.

The membrane so provided may have a non-stick coating applied to portions of the membrane, as described above. Portions of the membrane may be masked prior to application of the non-stick coating, so that those portions may remain uncoated, if desired. A flexible mask, as described above, may be applied to the membrane prior to application of the coating, and removed thereafter to leave uncoated portions of the membrane. In some embodiments, it may be advantageous to include the edge portion in the uncoated portion of the membrane to enhance sealing between the bead and the carrier head. In other embodiments, it may be advantageous to include the peripheral portion in the uncoated portion, also. In still other embodiments, it may be desired to include all but a central portion of the substrate engaging surface in the uncoated portion to have reliable sealing around the bead, reliable attachment of the substrate to the carrier head, and reliable releasing of the substrate when positive pressure is applied to the membrane. A membrane with an uncoated bead will generally achieve a leak rate of less than 0.2 psi/min.

A mask as described above may be made by forming a flexible, elongated masking sheath of any convenient cross-sectional shape, such as circular or rectangular, and creating a longitudinal opening down the length of the sheath to allow the mask to be applied to portions of the membrane. A mask so formed may be slipped over the edge portion of the membrane, for example, to shield the edge portion during application of the non-stick coating, and then the mask may be removed.

A membrane for a planarizing apparatus, as described above, may be formed as a flexible article with a flat central portion, a contoured peripheral portion, and a bead around the edge, and may have a non-stick coating applied by fitting a mask to a portion of the flexible article, coating the article with a non-stick coating, and removing the mask. A membrane may be formed by injecting a settable or curable liquid into a mold and allowing the liquid to cure or set into a flexible or pliable material. Heat or pressure may be applied to facilitate curing. A material that adheres to metal with a sticking force of at least 6.0 Pa may be helpful when an uncoated bead is used to enhance sealing by adhering to the carrier head. Such materials, examples of which are described above, may result in a disengagement force between the bead and the carrier head of at least about 0.5 mN.

In some embodiments, a mold may be provided that forms a roughened surface on portions of the membrane. The membrane thus formed may have a surface roughness at least about 10 pin, such as 15 pin or more, on portions thereof. Surface roughness on portions of the membrane that contact the substrate will reduce the sticking force of the substrate to the membrane to less than 0.02 lbs, enabling the substrate to disengage from the carrier head spontaneously when the vacuum chuck is released. In other embodiments, a surface of the membrane may be roughened by application of mechanical force after the membrane is molded.

While the foregoing is directed to various embodiments, other and further embodiments may be devised.

1. A membrane for a carrier head, comprising:
a membrane body formed of a polymer material, the membrane body including
a central portion having a mounting surface for engaging a substrate, wherein the mounting surface has an Ra roughness at least about 10 micro-inches, and wherein the roughness is such that the polymer material of the mounting surface adheres to a semiconductor material of the substrate with a sticking force less than about 0.02 lbs;
a peripheral portion extending from the central portion at an outer edge of the mounting surface; and
a bead at the edge of the peripheral portion for engaging a receiving structure in the carrier head, wherein the bead is smoother than the mounting surface such that the polymer material of the bead sticks to metal with a sticking tension of at least 6 Pa.

2. The membrane of claim 1, wherein the surface has an Ra roughness at least about 15 micro-inches.

3. (canceled)

4. The membrane of claim 1, wherein the surface adheres to the substrate with a sticking force less than about 0.01 lbs.

5-23. (canceled)

24. The membrane of claim 1, wherein the polymer materials includes one or more of silicone rubber, butyl rubber, natural rubber, EPDM rubber, or polyimide.

25. The membrane of claim 1, wherein the bead has a thickness greater than that of the central portion.

26. The membrane of claim 25, wherein the bead has a circular cross-section.
